(19) United States
(12) Patent Application Publication
(10) Pub. No.: US 2009/0085150 A1
(43) Pub. Date: Apr. 2, 2009

(54) Semiconductor device having silicon-on-insulator (SOI) structure and method of forming semiconductor device

(75) Inventor: Noriyuki Takao, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELECTRONICS CORPORATION, Kawasaki (JP)

(21) Appl. No.: 12/232,006

(22) Filed: Sep. 9, 2008

(30) Foreign Application Priority Data
Sep. 27, 2007 (JP) 2007-251932

(51) Int. Cl. H01L 29/00; H01L 21/762

(52) U.S. Cl. 257/510; 438/405; 257/E29.001; 257/E21.564

(57) ABSTRACT

A semiconductor device includes a substrate, an insulating layer formed on the substrate, an active layer formed on the insulating layer, and a metal layer formed on a back surface of the substrate, the substrate and the metal layer being in ohmic contact. By bringing the substrate and the metal layer into ohmic contact, the resistance difference between the substrate and the metal layer can be reduced.

### BACKGROUND OF THE INVENTION

1. Field of the Invention

The present invention relates to a semiconductor device, and particularly to a semiconductor device in which a metal thin film is formed on a back surface of a substrate having a silicon-on-insulator (SOI) structure.

2. Description of Related Art

Conventionally, a semiconductor device having an SOI structure in which an insulating film is formed between a supporting substrate and an active layer has been known, for example, as described in Japanese Laid Open Patent Application No. 2001-230392. An integrated circuit (IC) using the SOI structure is easily made high-voltage resistant, and is unlikely to cause a malfunction which might occur due to a latchup or an externally-caused surge. Therefore, IC's using the SOI structure are used for an electronic control circuit of an automobile and the like.

In an IC with the SOI structure mounted on an automobile or the like, a substrate is mounted on a lead frame inside an IC package by soldering so as to be able to withstand heat stress during mounting or a high-temperature environment during operation. Such a die mount by soldering allows a strong junction and has high resistance to repeatedly-loaded stress. The die mount by soldering also has excellent characteristics regarding heat conductivity and electric conductivity. On the other hand, a die mount by silver paste causes detachment or a crack of the silver paste when mechanical stress due to repeated temperature change is applied to a junction portion.

When performing the die mount by soldering, it is necessary to form a metal thin film on a back surface of the IC as a junction portion with the lead frame.

FIG. 11 is a vertical-sectional view showing a configuration of a semiconductor device of a related art. An active layer 113 is formed on a low concentration substrate 111 with an oxide film 112 interposed therebetween. On a surface of the low concentration substrate 111 opposite to the surface on which the oxidized film 112 is formed, a metal thin film 115 is formed. The metal thin film 115 is a junction surface to be joined with the lead frame.

FIG. 12 is a sectional view showing a configuration of an alternative semiconductor device of a related art. An active layer 123 is formed on a low concentration substrate 121 with an oxide film 122 interposed therebetween. On a surface of the active layer 123 in contact with the oxide film 122, a high concentration layer 124 including highly concentrated impurities is formed. By providing the high concentration layer 124 to the active layer 123 in this manner, the resistance of the active layer 123 is intended to be lowered in some cases. The active layer 123 is formed with a deep trench 123a from its surface to the oxide film 122. Inside the trench 123a, an insulating material 126 is formed. The trench 123a and the insulating material 126 are provided to separate the active layers 123 on their both sides like islands. By providing the trench 123a, it can be configured such that a semiconductor element formed in one of the active layers 123 does not cause a malfunction, which might be caused by current flowing through the other adjacent active layer 123, even during a high-frequency operation.

### SUMMARY OF THE INVENTION

However, in the IC having the SOI structure shown in FIG. 11, the metal thin film is formed on the back surface of the Si substrate of low concentration. Accordingly, a surface of the metal thin film 115 and a surface of the Si substrate is in Schottky contact.

FIG. 13 is a view showing a flow of surge current in the semiconductor device shown in FIG. 11. FIG. 13 also shows an equivalent circuit of the semiconductor device. In the equivalent circuit, an insulating film 112 sandwiched between the active layer 113 and the low concentration substrate 111 is shown as a capacitor C. Since the low concentration substrate 111 and the metal thin film 115 are in Schottky contact, a circuit between the low concentration substrate 111 and the metal thin film 115 is shown as a Schottky barrier diode SBD.

In the active layer 113, a circuit element (not shown) such as a transistor is formed. External noise flows in the active layer 113 through the circuit element and becomes a surge current. When the minus surge current occurs in the low concentration substrate 111 from the metal thin film 115 side due to the externally-caused external noise or the like outside the semiconductor device, the minus surge current flows in a forward direction of the Schottky barrier diode SBD, and flows in toward the low concentration substrate 111 side. Meanwhile, the plus surge current occurred in the active layer 113 flows in the Schottky barrier diode SBD, but the current hardly flows from the low concentration substrate 111 to the metal thin film 115 since this direction is a reverse voltage direction of the Schottky barrier diode SBD. By such a rectification effect of Schottky contact, electric charge is gradually accumulated in the low concentration substrate 111 to increase the electric potential of the low concentration substrate 111. As a result, there is a problem of inducing a malfunction of the semiconductor element formed in the active layer 113 that is formed above the low concentration substrate 111.

FIG. 14 is a view showing the surge current flowing in the alternative semiconductor device shown in FIG. 13. FIG. 14 also shows an equivalent circuit of the alternative semiconductor device. As shown in FIG. 14, since the low concentration substrate 121 and a metal thin film 125 are in Schottky contact, a contact resistance of the low concentration substrate 121 and the metal thin film 125 can be deemed equivalent to that of the Schottky barrier diode SBD. This semiconductor device is in the state where the plus surge current occurred in the active layer 123 side hardly flows into the metal thin film 125 side due to the rectification characteristic of the Schottky barrier diode SBD. Since the high concentration layer 124 is formed on the oxide film 122, the plus surge current occurred does not flow into the Schottky barrier diode SBD side, but easily flows into the adjacent active layer 123 side. As a result, the active layers 123 which have been supposedly separated by the trench 123a and the insulating material 126 influences each other, causing a problem that the semiconductor element formed in the active layer 123 malfunctions.

A semiconductor device according to one exemplary aspect of the present invention includes a substrate, an insulating layer formed on the substrate, an active layer formed on the insulating layer, and a metal layer formed on a back surface of the substrate, the substrate and the metal layer being in ohmic contact.

By bringing the substrate and the metal layer into ohmic contact in this manner, it is possible to reduce the contact resistance between the substrate and the metal layer and to reduce the rectification characteristic at the contact surface.

One exemplary aspect of a method of manufacturing a semiconductor device according to in the present invention is a method of manufacturing a semiconductor device including a substrate, an insulating layer formed on the substrate, and an active layer formed on the insulating layer. The method includes forming a metal layer on a surface of the substrate opposite to a surface on which the insulating layer is formed so that the metal layer and the substrate are in ohmic contact.

By forming the metal layer so as to make ohmic contact with the substrate in this manner, it is possible to reduce the contact resistance between the substrate and the metal layer and to reduce the rectification characteristic at the contact surface.

According to one aspect of the semiconductor device of the present invention, the characteristics of the semiconductor device can be improved.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a sectional view showing one configuration example of a semiconductor device according to a first embodiment of the present invention;

FIGS. 2A to 2G are views showing manufacturing steps of the semiconductor device according to the first embodiment;

FIGS. 3A and 3B are views showing surge currents flowing in the semiconductor devices according to the first embodiment;

FIG. 4 is a sectional view showing one configuration example of a semiconductor device according to a second embodiment of the present invention;

FIGS. 5A to 5F are views showing manufacturing steps of the semiconductor device according to the second embodiment;

FIG. 6 is a view showing a relation between depth (μm) and impurity concentration (cm⁻³) when a high concentration substrate includes 3×10¹⁸ cm⁻³ of Sb;

FIG. 7 is a view showing a relation between depth (μm) and impurity concentration (cm⁻³) when the high concentration substrate includes 2×10¹⁹ cm⁻³ of As;

FIG. 8 is a view showing a relation between depth (μm) and impurity concentration (cm⁻³) when the high concentration substrate includes 2×10¹⁹ cm⁻³ of B;

FIG. 9 is a view showing a relation between depth (μm) and impurity concentration (cm⁻³) when the high concentration substrate includes 7×10¹⁸ cm⁻³ of Sb;

FIGS. 10A and 10B are views showing surge currents flowing in semiconductor devices 20 according to a second embodiment;

FIG. 11 is a view showing a configuration of a semiconductor device of a related art;

FIG. 12 is a view showing a configuration of an alternative semiconductor device of a related art;

FIG. 13 is a view showing a flow of surge current in the semiconductor device of FIG. 11; and

FIG. 14 is a view showing a flow of surge current in the alternative semiconductor device of FIG. 12.

### DETAILED DESCRIPTION OF THE EXEMPLARY EMBODIMENTS

### First Exemplary Embodiment

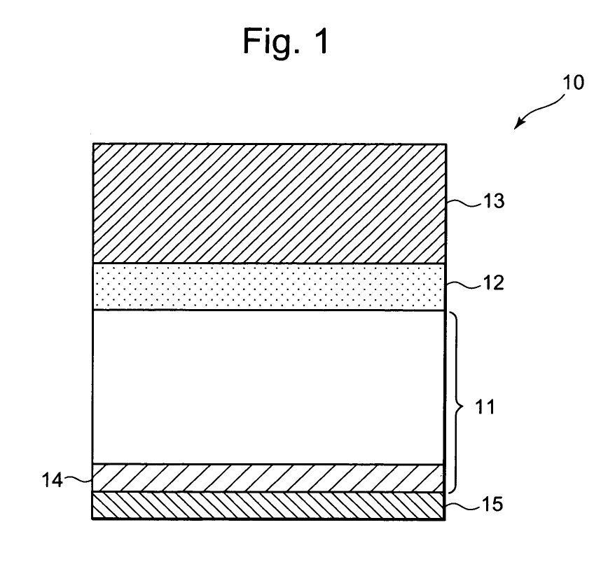

FIG. 1 is a sectional view showing a semiconductor device 10 according to a first exemplary embodiment of the present invention. The semiconductor device 10 according to the present invention is characterized by having a substrate (low concentration substrate 11), an insulating layer (oxide film 12) formed on the substrate, an active layer 13 formed on the insulating layer, and a metal layer (metal thin film 15) formed on a back surface of the substrate, the substrate and the metal layer being in ohmic contact.

As shown in FIG. 1, the semiconductor device 10 according to the first exemplary embodiment has the low concentration substrate 11, the oxide film 12, the active layer 13, a high concentration layer 14, and the metal thin film 15. The low concentration substrate 11 is a semiconductor substrate, and is a silicon substrate including impurities of low concentration such as phosphor. The low concentration substrate 11 can be formed by a pulling method or the like. An impurity concentration of the low concentration substrate 11 is generally approximately 1×10¹⁵ cm⁻³, and may be conditionally approximately from 1×10¹⁴ to 1×10¹⁶ cm⁻³. The low concentration substrate 11 is formed with the high concentration layer 14 on the back surface. The high concentration layer 14 has a higher impurity concentration compared to other portions of the low concentration substrate 11. The high concentration layer 14 can be formed by doping with phosphor of high concentration by ion implantation. The dose amount is approximately 1×10⁻¹⁵ cm⁻², and the energy amount is approximately several tens of keV.

The oxide film 12 is formed on the low concentration substrate 11. The oxide film 12 can be formed by, for example, a steam oxidation method. The film thickness of the oxide film 12 is set to be thick enough to ensure insulation between the low concentration substrate 11 and the active layer 13. The oxide film 12 is configured to achieve voltage insulation of approximately 5 MV/cm to 8 MV/cm. The active layer 13 is formed on the oxide film 12. The active layer 13 is formed with a semiconductor element (not shown) by ion implantation or thin film formation. The semiconductor element formed in the active layer 13 is connected by, for example, an aluminum wiring. When a completed IC is mounted on an automobile or the like, the semiconductor element formed in the active layer 13 is applied with a voltage of approximately 0 V to 10 V.

The metal thin film 15 is formed on the high concentration layer 14 side of the low concentration substrate 11. If the impurity concentration of the high concentration layer 14 is 1×10¹⁹ cm⁻³ or higher, the contact between the low concentration substrate 11 and the metal thin film 15 is ohmic contact. The high concentration layer 14 is provided so as to avoid Schottky contact between the low concentration substrate 11 and the metal thin film 15. Ohmic contact referred herein does not necessarily require an exact linear relation between a flowing current and an applied voltage. In addition, ohmic contact shown herein allows a rectification characteristic to a degree that a electric potential fluctuation of the low concentration substrate 11 does not contribute to a malfunction of the semiconductor element formed in the active layer 13. For example, when the semiconductor device 10 is mounted on an automobile, a voltage of approximately 5 V is applied to the semiconductor element in the active layer 13. In such a case, if the electric potential fluctuation of the low concentration substrate 11 is approximately ±10 V, a malfunction of the semiconductor element in the active layer 13 presumably does not occur. For this reason, a contact between the low concentration substrate 11, in which the electric potential fluctuation is approximately ±10 V, and the metal thin film 15 is herein referred to as “ohmic contact.”

The metal thin film 15 can be formed by deposition or sputtering. The metal thin film 15 can be formed by laminating metal films. For example, the metal thin film 15 can be formed by sequentially accumulating Ti and/or Cr as a first layer, and accumulating Ni as a second layer and Ag as a third layer from the high concentration layer 14 side.

The semiconductor device 10 configured in this manner is connected to a lead frame (not shown) by soldering. The outer circumference of the semiconductor device 10 is covered by a package (not shown) in a connected state with the lead frame by soldering. The semiconductor device 10 configured in this manner is mounted on, for example, a control circuit of an automobile or the like.

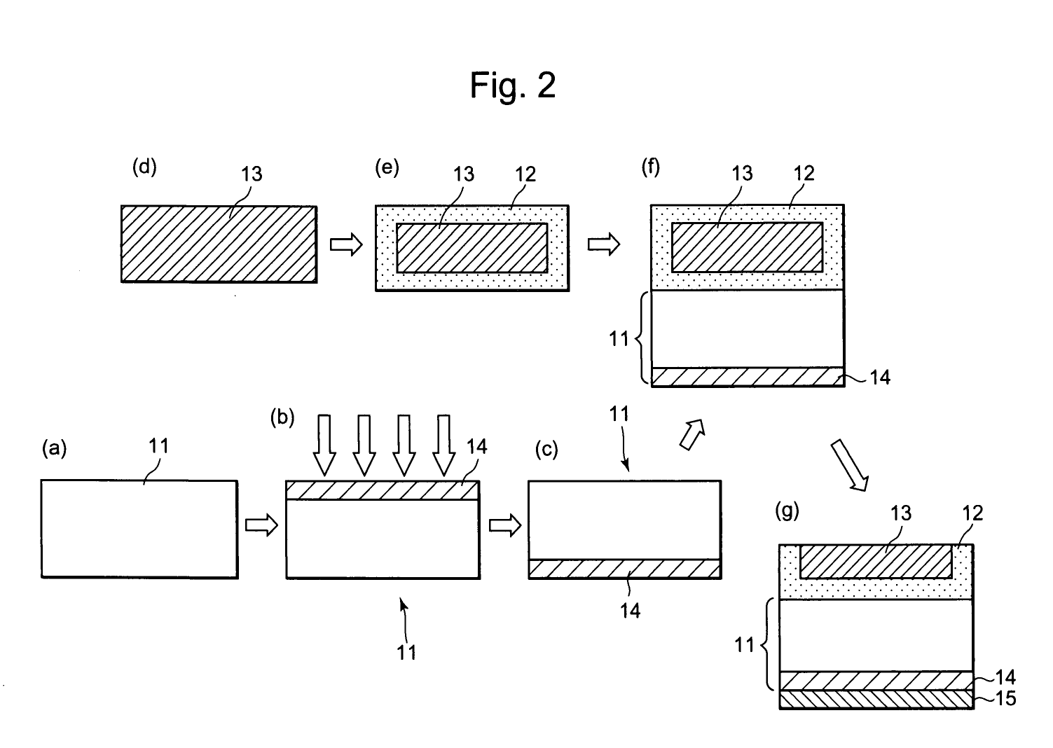

Next, a method of manufacturing the semiconductor device 10 configured in this manner will be described. FIGS. 2A to 2G show an example of manufacturing steps of a wafer before being divided into individual chips as the semiconductor devices 10.

First, a silicon substrate including low concentration impurities is formed by the pulling method as shown in FIG. 2A. Thus, the low concentration substrate 11 is formed. Ion implantation is performed to a first surface of the low concentration substrate 1 1 to implant high concentration impurities (for example, phosphor) in FIG. 2B. Thus, the high concentration layer 14 is formed in the first surface of the low concentration substrate 11 to a predetermined depth. The impurity concentration of the high concentration layer 14 is approximately 1×10¹⁹ cm⁻³. Then, the low concentration substrate 11 is placed such that the high concentration layer 14 is on the opposite side of the surface to which the active layer 13 is connected in FIG. 2C.

Meanwhile, as shown in FIG. 2D, a silicon substrate including boron is formed by the pulling method. Thus, the active layer 13 is formed. The concentration of boron is approximately 1×10¹⁵ cm⁻³. The oxide film 12 is formed on the surface of the active layer 13 in FIG. 2E. For forming the oxide film 12, the steam oxidation method may be used, for example. The oxide film 12 is formed to have a thickness thick enough to ensure insulation between the low concentration substrate 11 and the active layer 13. For example, the oxide film 12 is formed to achieve voltage/thickness insulation of approximately 5 MV/cm to 8 MV/cm.

As described in FIG. 2F, the surface of the low concentration substrate 11 on the opposite side of the high concentration layer 14 shown in FIG. 2C and the active layer 13 formed with the oxide film 12 shown in FIG. 2E are bonded. Then, annealing is performed in FIG. 2F. Thus, the bond between the low concentration substrate 11 and the active layer 13 becomes strong. As shown in FIG. 2G, the oxide film 12 on the surface of the active layer 13 opposite to the surface contacting the low concentration substrate 11 is grinded or polished to expose the active layer 13. The metal thin film 15 is formed on a back surface of the low concentration substrate 11 in FIG. 2G. Thus, the low concentration substrate 11 and the metal thin film 15 are brought into ohmic contact.

The wafer configured in this manner is divided into individual chips by a dicing device or the like. The each divided chip is mounted on the lead frame by soldering. By the soldering, the lead frame and the low concentration substrate 11 can be connected strongly. Note that the oxide film 12 is also formed on a side surface of the semiconductor device in the semiconductor device shown in FIG. 2G. However, this shows the oxide film 12 formed on the outer circumference of one wafer, and the oxide film 12 is not formed on a side surface of the semiconductor device which has been made into an individual chip. That is, by dividing the whole of the semiconductor devices of which the outer circumference is covered with the oxide film 12, the semiconductor device 10 shown in FIG. 1 is obtained.

Note that the step of forming the high concentration layer 14 of FIG. 2E may be performed as the final step of the wafer manufacturing. In this case, after the back surface of the wafer in which the active layer 13 and the low concentration substrate 11 are joined is grinded, ion implantation of the high concentration impurities is performed on the back surface of the low concentration substrate 11. Then, the metal thin film 15 is formed by sputtering or deposition. Such a configuration also provides an effect of this embodiment since the low concentration substrate 11 and the metal thin film 15 are brought into ohmic contact.

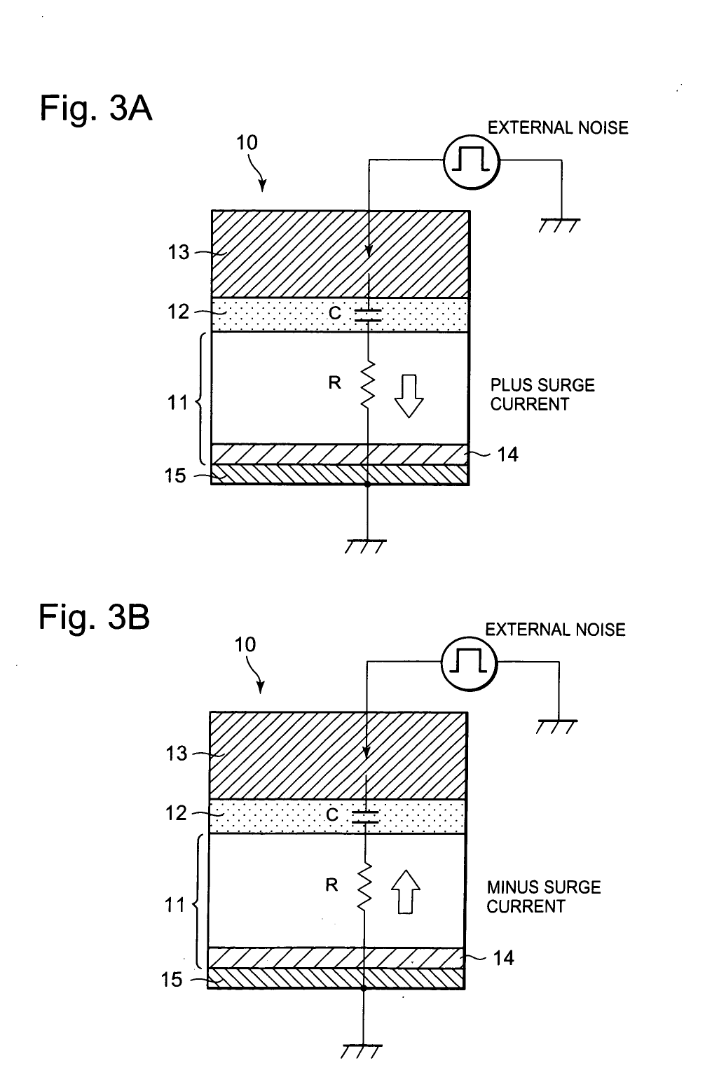

FIGS. 3A and 3B are views showing surge currents flowing in the semiconductor devices 10 according to the first embodiment. FIGS. 3A and 3B also show equivalent circuits of the semiconductor devices 10. A parasitic capacitance of the oxide film 12 sandwiched between the active layer 13 and the low concentration substrate 11 is referred to as the capacitor C. Since the low concentration substrate 11 and the metal thin film 15 are brought into ohmic contact, the contact between the low concentration substrate 11 and the metal thin film 15 is shown as a resistance R. As shown in FIG. 3A, the active layer 13 is formed with a circuit element such as a transistor. In the circuit element, the plus surge current which flows from the active layer 13 to the low concentration substrate 1 1 occurs due to an external noise or the like. The plus surge current flows to the metal thin film 15 via the resistance R.

Meanwhile, as shown in FIG. 3B, the minus surge current occurs in the metal thin film 15 due to an external noise or the like. The minus surge current flowed from the metal thin film 15 to the low concentration substrate 11 flows to the active layer 13 side via the resistance R. In this manner, in the semiconductor device 10, the plus surge current and the minus surge current can flow in both directions via the resistance R. As a result, a rise in electric potential can be reduced by a stored charge of the low concentration substrate 11.

Thus, by forming the high concentration layer 14 in the low concentration substrate 11, the contact resistance between the low concentration substrate 11 and the metal thin film 15 can be reduced in the semiconductor device 10 according to this embodiment. Accordingly, it is possible to prevent the fluctuation (rise) of a substrate electric potential and to prevent a malfunction of the circuit element formed in the active layer 13. As a result, the characteristics of the semiconductor device 10 can be improved.

### Second Exemplary Embodiment

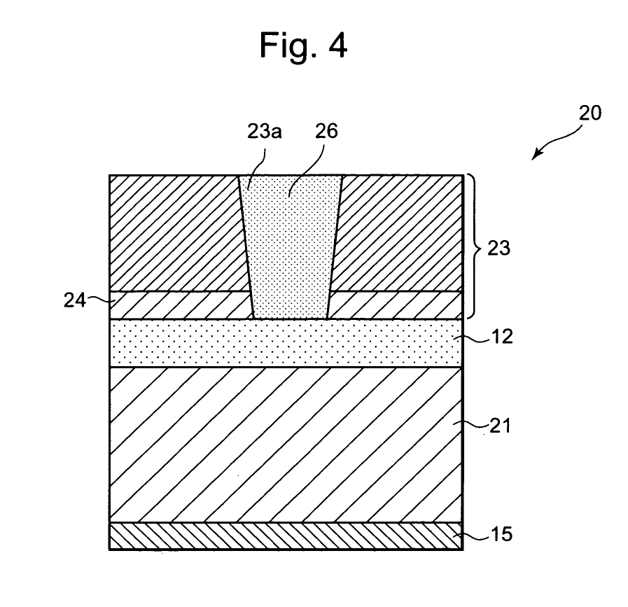

FIG. 4 is a vertical-sectional view showing a semiconductor device 20 according to a second exemplary embodiment of the present invention. As shown in FIG. 4, the semiconductor device 20 includes a high concentration substrate 21, the oxide film 12, an active layer 23, and the metal thin film 15. The high concentration substrate 21 is a semiconductor substrate, and is a silicon substrate including impurities such as phosphor. The high concentration substrate 21 can be formed by a pulling method or the like. The impurity concentration of the high concentration substrate 21 is preferably 1×10¹⁸ cm⁻³ or higher. If the impurity concentration is 1×10¹⁸ cm⁻³ or higher, then the contact with the metal thin film 15 becomes ohmic contact with a low reverse voltage of 4 V or less. Any of different kinds of impurities can be used as the impurity included in the high concentration substrate 21. For example, Sb, As, P, and B may be used as the impurities.

Ohmic contact referred herein does not necessarily require an exact linear relation between a flowing current and an applied voltage. Ohmic contact shown herein accepts a rectification characteristic to a degree that an electric potential fluctuation of the low concentration substrate 21 does not contribute to a malfunction of the semiconductor element formed in the active layer 23.

The oxide film 12 is formed in a thickness which can ensure insulation between the active layer 23 and the high concentration substrate 21. The oxide film 12 is configured to achieve voltage insulation of approximately 5 MV/cm to 8 MV/cm. The oxide film 12 is formed by, for example, steam oxidation. Generally, the impurity concentration in the oxide film 12 is lower than that in the high concentration substrate 21. The oxide film 12 achieves electric insulation with a film thickness of 1 μm under approximately 500 V.

The active layer 23 has a high concentration layer 24 on the oxide film 12 side thereof. The high concentration layer 24 is provided so as to lower the resistance of the active layer 23. The active layer 23 is formed with a trench 23a reaching the oxide film 12 from the surface of the active layer 23. Inside the trench 23a, an insulating material 26 is formed. The trench 23a and the insulating material 26 are provided to divide the active layers 23 into both sides. That is, the trench 23a is provided to separate the active layers 23 like islands. By providing the trench 23a, it is possible to easily control the operations of the active layers 23 separately from each other even when elements of the active layers 23 are operated with high frequency.

The metal thin film 15 is formed on a surface of the high concentration substrate 21 opposite to a surface on which the oxide film 12 is formed. The metal thin film 15 can be formed by laminating metal films. For example, the metal thin film 15 can be formed by sequentially accumulating Ti and/or Cr as a first layer, and accumulating Ni as a second layer and Ag as a third layer from the high concentration layer 14 side.

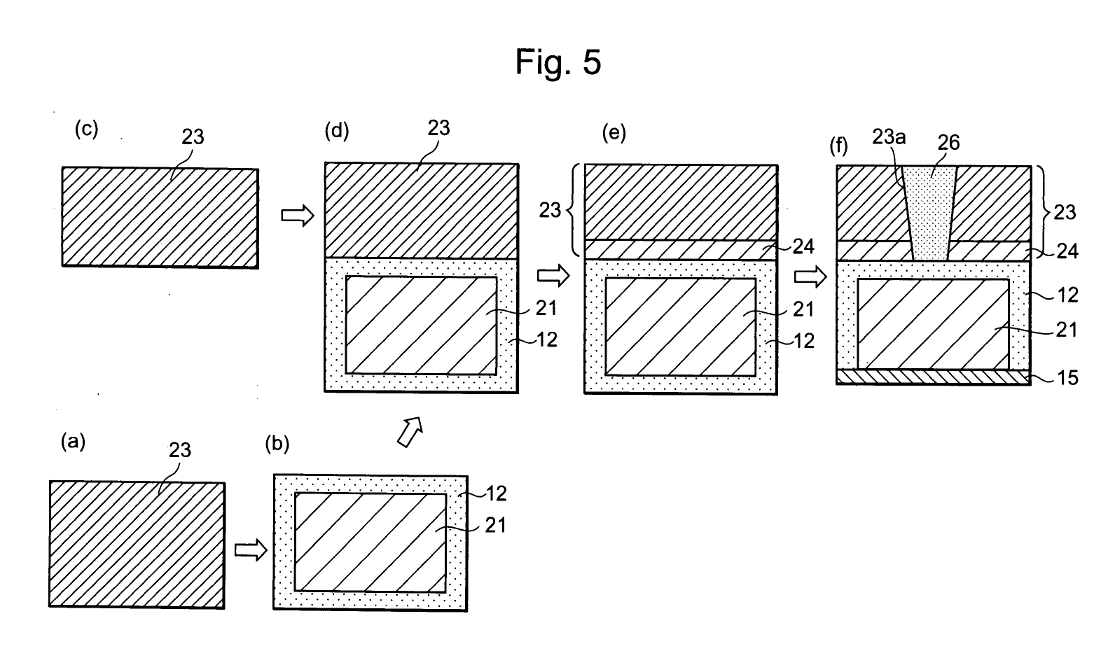

Next, a method of manufacturing the semiconductor device 20 configured in this manner will be described. FIGS. 5 to 5F are views showing manufacturing steps of the semiconductor device 20 according to the second exemplary embodiment. Note that FIGS. 5A to 5F show manufacturing steps of a wafer before being made into a chip. First, a silicon substrate including high concentration impurities is formed by the pulling method or the like, as shown in FIG. 5A. Thus, the high concentration substrate 21 is formed. Note that the impurity concentration of the high concentration substrate 21 is approximately 1×10¹⁸ cm⁻³. The oxide film 12 is formed by the steam oxidation or the like on the surface of the high concentration substrate 21 in FIG. 5B. Generally, the impurity concentration in the oxide film 12 is lower than that of the high concentration substrate 21. In this oxidation step, the high concentration impurities in the silicon is taken in the oxide film 12 simultaneously with the oxidation. Meanwhile, a silicon substrate is generated by the pulling method in FIG. 5C. Thus, the active layer 23 is formed. The impurity concentration of the active layer 23 is approximately 1×10¹⁴ cm⁻³ to 1×10¹⁶ cm⁻³. The active layer 23 is formed to include boron having a concentration of, for example, 1×10¹⁵ cm⁻³.

As shown in FIG. 5D, the high concentration substrate 21 shown in FIG. 5B and the active layer 23 formed with the oxide film 12 on its surface shown in FIG. 5C are bonded. Then, annealing is performed in FIG. 5E. Thus, the impurities in the oxide film 12 are thermally diffused in the active layer 23. As a result, the high concentration layer 24 is formed on the oxide film 12 side of the active layer 23. Note that a peak value of the impurity concentration of the high concentration layer 24 is lower than that of the high concentration substrate 21. Then, the active layer 23 is formed with a semiconductor element (not shown) by repeating thin film accumulation or etching, in FIG. 5G. Ion implantation and heat treatment such as oxidation are also performed for forming the semiconductor element. A deep trench 23a is formed in the active layer 23 simultaneously with the formation of the semiconductor element, and an insulating material is buried inside the trench 23a. Thus, the active layers 23 are separated like islands. After the semiconductor element and the trench are formed, an aluminum wiring is connected to the semiconductor element.

Further, the oxide film 12 on the surface of the high concentration substrate 21 opposite to the surface formed with the active layer 23 is grinded. Thus, the active layer 23 is exposed. Note that, in order to further reduce the low contact resistance, a back surface of the high concentration substrate 21 may be etched into a mirror surface. The metal thin film 15 is formed by performing deposition or sputtering on this surface. Thus, the metal thin film 15 and the high concentration substrate 21 are brought into ohmic contact (non-Schottky contact). The wafer formed by the above steps is divided by a dicing device or the like. Thus, the semiconductor device 20 shown in FIG. 3 is obtained. The semiconductor device 20 is die-mounted to a lead frame (not shown) by soldering.

The impurities in the oxide film 12 are thermally diffused in the active layer 23 also by heat treatment in the semiconductor manufacturing steps. Therefore, in order to obtain a desired distribution of the impurities after the manufacturing steps end, it suffices that the impurity concentration in the high concentration substrate 21 and the temperature or time of the heat treatment in the steps be considered.

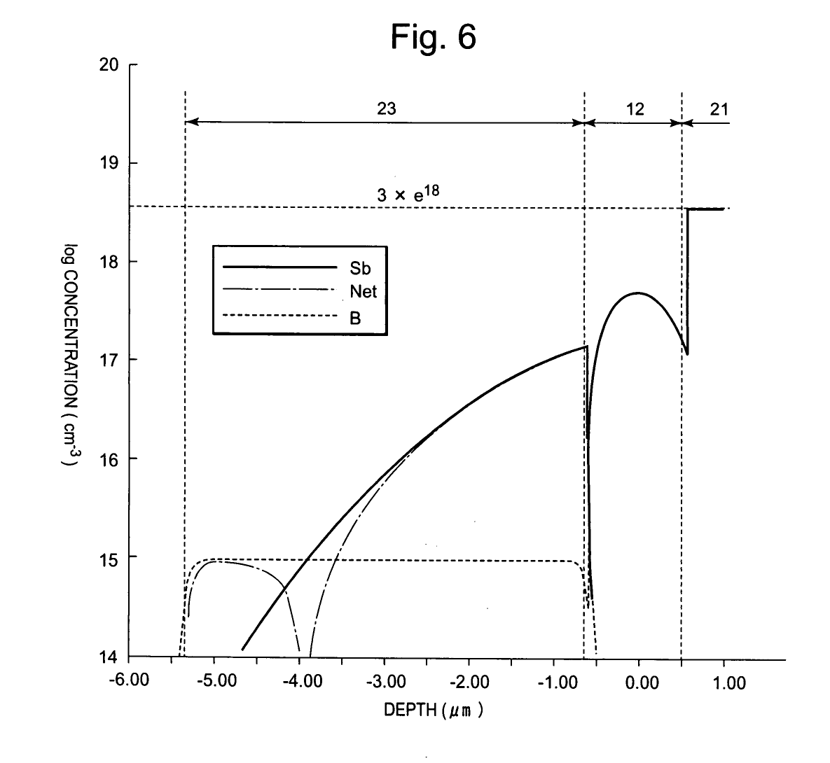

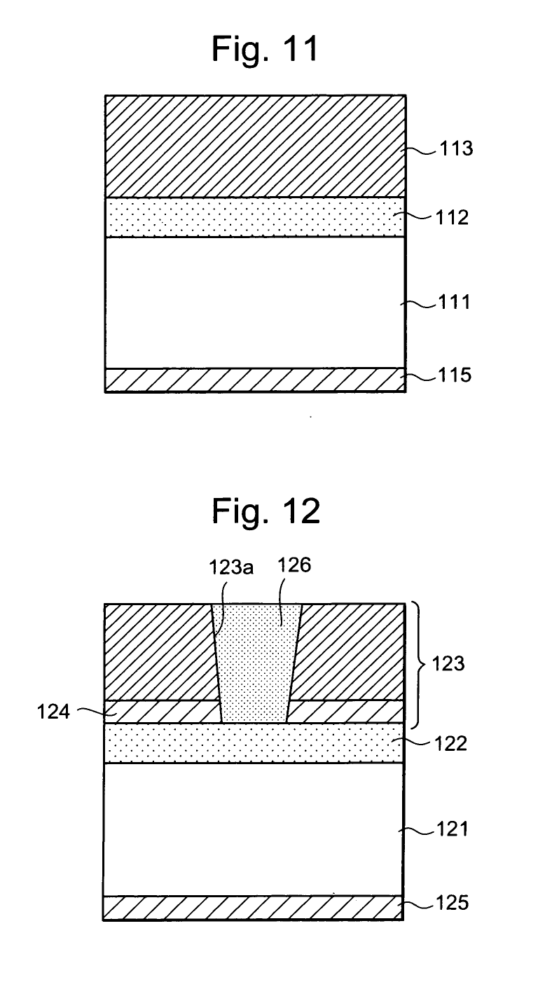

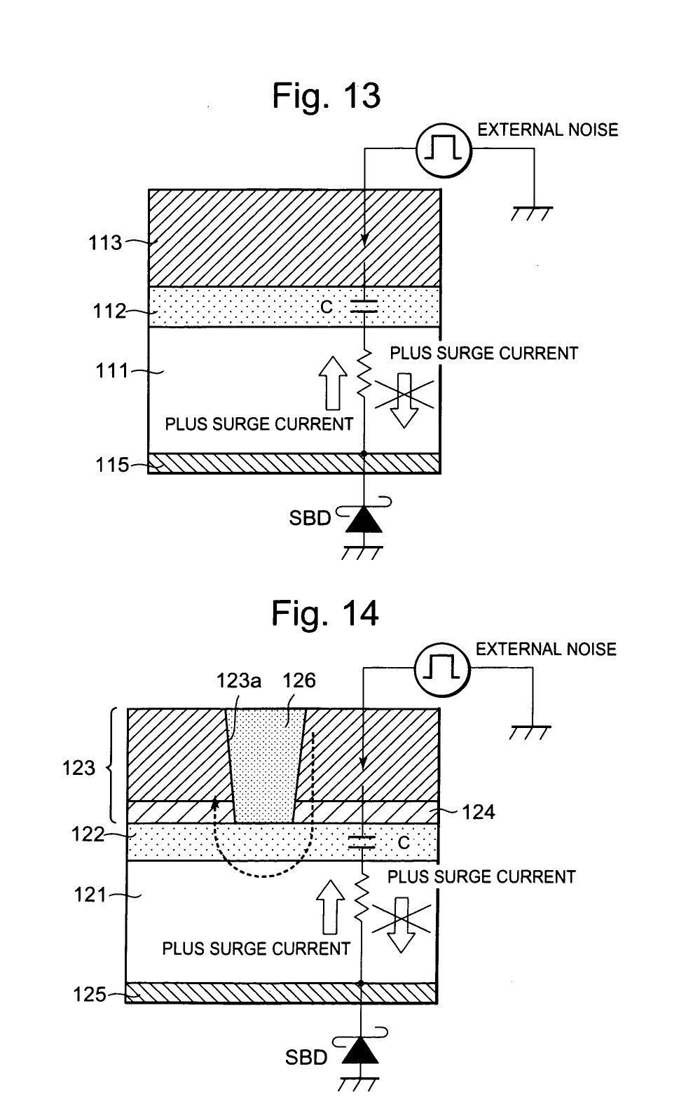

FIGS. 6 to 11 are simulation results showing relations between depth (μm) and impurity concentration (cm⁻³) when the high concentration substrates 21 having different kinds of impurities or impurity concentrations are used. Note that the impurity concentration of the ordinate is indicated by a scale of logarithms (log). FIG. 6 is a simulation result showing the relation between the depth (μm) and the impurity concentration (cm⁻³) when a substrate including 3×10¹⁸ cm⁻³ of Sb is used as the high concentration substrate 21. In FIG. 6, a solid line shows the concentration of Sb, a dashed-dotted line shows a concentration difference (Net) of n-impurities and p-impurities, and a dotted line shows the concentration of B. For example, in a portion where the dashed-dotted line is substantially zero when the depth is 4.00 μm, the n-impurities and the p-impurities are each included with the same concentration. As shown in FIG. 6, it can be seen that the Sb included in the high concentration substrate 21 is thermally diffused in the active layer 23 via the oxide film 12.

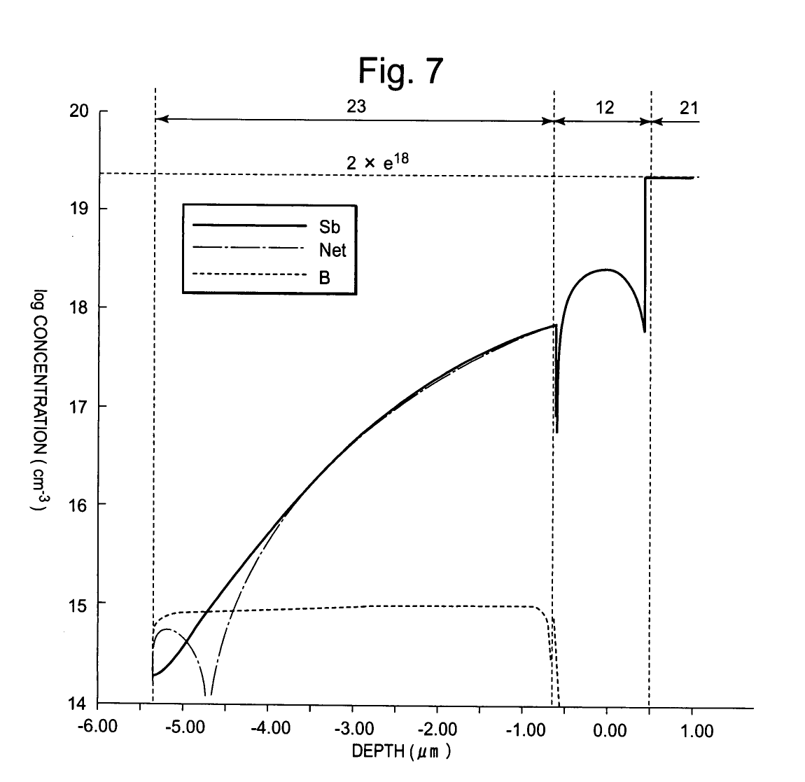

FIG. 7 is a simulation result showing the relation between the depth (μm) and the impurity concentration (cm⁻³) when a substrate including 2×10¹⁹ cm⁻³ of Sb is used as the high concentration substrate 21. In FIG. 7, a solid line shows the concentration of Sb, a dashed-dotted line shows a concentration difference (Net) of n-impurities and p-impurities, and a dotted line shows the concentration of B. In this manner, since the concentration of Sb included in the high concentration substrate 21 is higher in the substrate shown in FIG. 7 than the substrate shown in FIG. 6, it can be seen that the Sb of the high concentration substrate 21 is diffused to the surface side of the active layer 23.

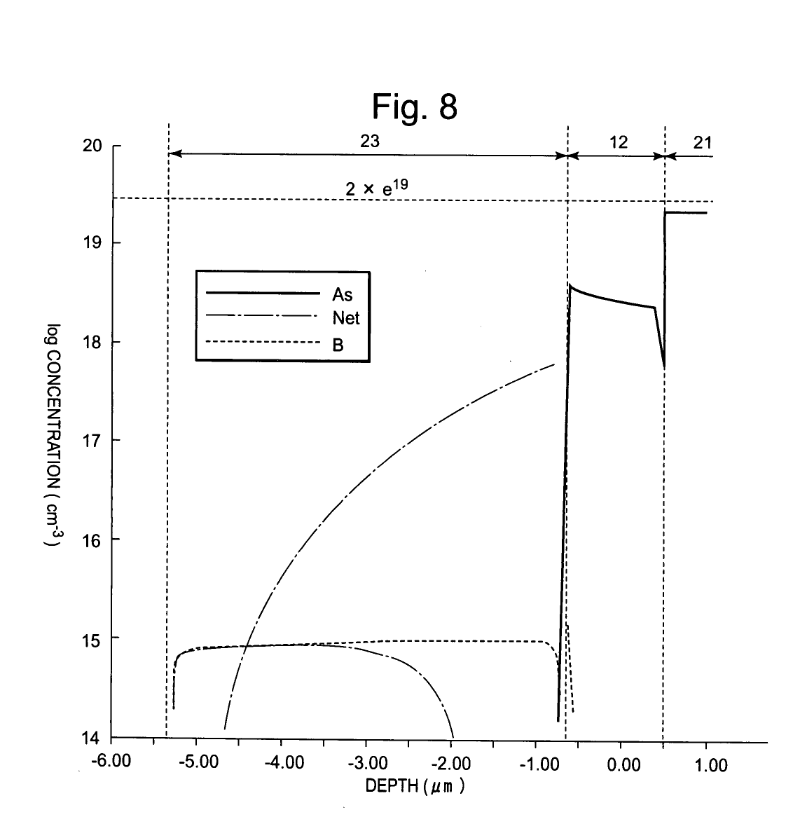

FIG. 8 is a simulation result showing the relation between the depth (μm) and the impurity concentration (cm⁻³) when a substrate including 2×10¹⁹ cm⁻³ of As is used as the high concentration substrate 21. In FIG. 8, a solid line shows the concentration of As, a dashed-dotted line shows a concentration difference (Net) of n-impurities and p-impurities, and a dotted line shows the concentration of B. In this manner, although the concentration of the substrate shown in FIG. 8 is the same as that of Sb in the substrate shown in FIG. 7, it can be seen that the As is not diffused to the surface side of the active layer 23 like as Sb.

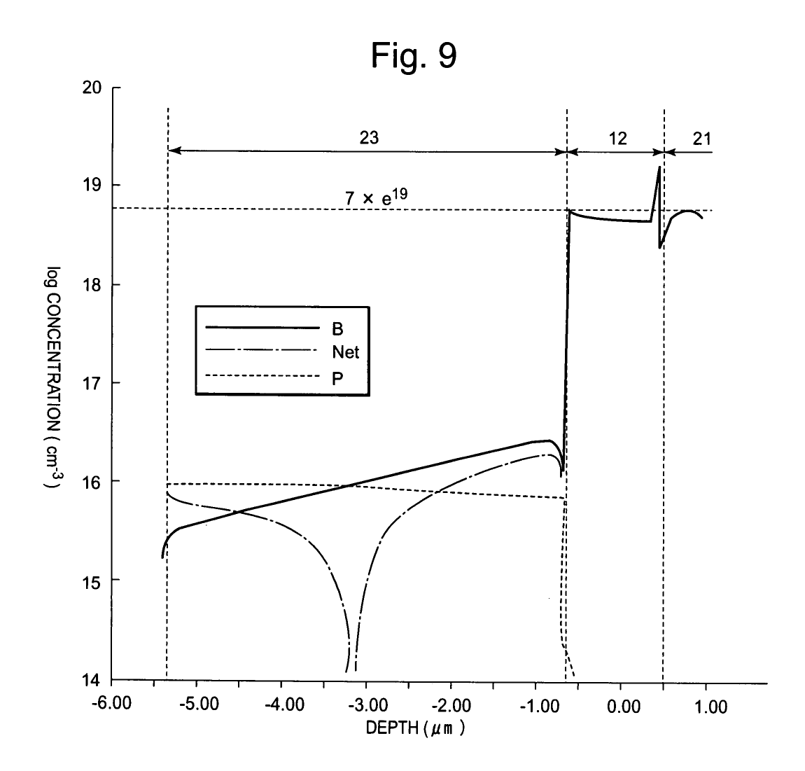

FIG. 9 is a simulation result showing the relation between the depth (μm) and the impurity concentration (cm⁻³) when a substrate including 7×10¹⁸ cm⁻³ of B is used as the high concentration substrate 21. In FIG. 9, a solid line shows the concentration of B, a dashed-dotted line shows a concentration difference (Net) of n-impurities and p-impurities, and a dotted line shows the concentration of P.

In this manner, in the semiconductor device 20 according to the second embodiment, a desired concentration distribution of impurities can be easily obtained by selecting the kind or concentration of the impurities included in the high concentration substrate 21.

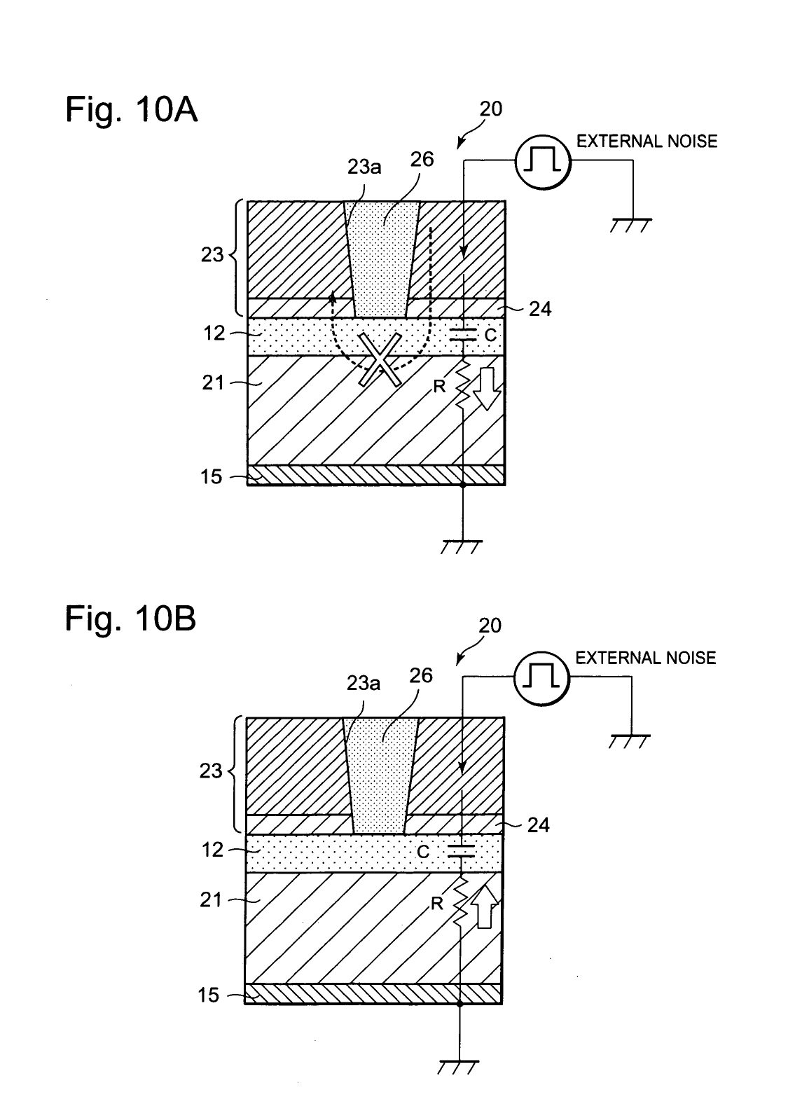

FIGS. 10A and 10B are views showing surge currents flowing in the semiconductor devices 20 according to the second exemplary embodiment. FIGS. 10A and 10B also show equivalent circuits of the semiconductor devices 20. A parasitic capacitance of the oxide film 12 sandwiched between the active layer 23 and the high concentration substrate 21 is referred to as the capacitor C. Since the high concentration substrate 21 and the metal thin film 15 are brought into ohmic contact, the contact between the low concentration substrate 11 and the metal thin film 15 is shown as a resistance R. As shown in FIG. 10A, the plus surge current occurs from the active layer 13 to the high concentration substrate 21 due to voltage applied to a circuit element or the like (not shown). The plus surge current flows to the metal thin film 15 side via the high concentration substrate 21.

Meanwhile, as shown in FIG. 10B, the minus surge current occurs on the metal thin film 15 side due to an external noise or the like. The occurred minus surge current flows to the high concentration substrate 21 side via the resistance R. In this manner, in the semiconductor device 20, the occurred the plus surge current and the minus surge current can flow in both directions via the resistance R. As a result, a electric potential fluctuation of the high concentration substrate 21 due to a rectification effect can be reduced, and a malfunction of the semiconductor element formed on the high concentration substrate 21 can be prevented.

In this manner, in the semiconductor device according to the second exemplary embodiment, the surge current occurred in the active layer 23 can be flowed to the high concentration substrate 21 side in the same manner as that of the first embodiment. Thus, the rectification effect by the surge current which occurs repeatedly can be reduced. Thus, a malfunction of the circuit element due to the plus surge current can be prevented, and the performance of the semiconductor device 10 can be improved.

In related semiconductor device of FIG. 12, an oxide film is formed on a low concentration substrate, and a high concentration layer 124 is formed thereon. In such a related semiconductor device, current hardly flows from the high concentration layer 124 to the low concentration layer 12 side, and the surge current occurred on the high concentration layer side flows out to the adjacent active layer 123. On the other hand, since the concentration is high in the entire substrate in this embodiment, a substrate electric potential hardly fluctuates. Therefore, the plus surge current occurred on the high concentration layer 24 side does not flow out to the adjacent active layer 23, and flows to the high concentration substrate 21 side. Thus, since the connection between the active layers 23 via a capacitance C of the SOI insulating film is reduced, the separation between the active layers 23 can be unaffected even during high frequency operation.

The effect of this embodiment will be specifically examined using a general substrate of 13 Ω·cm as a comparative example. With the general substrate of 13 Ω·cm, there is a parasitic resistance of 1.3Ω when the thickness of the substrate is 0.3 mm and the area is 3 mm². On the other hand, with the semiconductor device 20 according to this embodiment, the parasitic resistance is 10 mΩ when the high concentration substrate 21 of 0.1Ω is used, and the parasitic resistance becomes sufficiently lower than that of the general substrate. In a large-area output transistor having a collector or a drain on a back surface side, the insulating film becomes a parasitic capacitance of 70 pF with an area of 2 mm². According to a specification of the Electronic Industries Association of Japan (EIAJ) used for a test method of semiconductor devices or in an ESD immunity test such as an electro-optical sampling (EOS) method, a surge is applied to the semiconductor device at several hundred volts and with a peak current of ten-odd amperes.

In the case of the general substrate of 13 Ω·cm, the peak current is approximately ten-odd amperes, and a substrate electric potential is expected rise in an amount of 1.3Ω×10 A=approximately 10 V. The rise of the substrate electric potential gives an electric influence to the adjacent active layer separated by the insulating layer. On the other hand, when the high concentration substrate 21 of 0.1Ω according to this embodiment is used, the electric potential fluctuation of the substrate when the surge is applied to the semiconductor device 20 at several hundred volts and with a peak current of ten-odd amperes, the electric potential of the substrate can be suppressed to approximately 1 V. Thus, the electric influence to the adjacent active layer 23 can be reduced, and the adjacent active layers 23 can be electrically separated by the insulating material 26 and the oxide film 12 even during high frequency operation.

By using the high concentration substrate 21 and forming the metal thin film 15 on the back surface of the high concentration substrate 21 in which the active layer 23 is not formed in this manner, the semiconductor device 2 according to the second embodiment can prevent the electric potential fluctuation of the high concentration substrate 21. Thus, a malfunction of an element of the active layer 23 caused by the electric potential of the substrate can be prevented.

In the semiconductor device 20 according to the second exemplary embodiment, the high concentration layer 24 can be easily formed in the active layer 23 by bonding the high concentration substrate 21 and the active layer 23 via the oxide film 12 and performing the heat treatment. In the semiconductor device of the related art, ion implantation has been performed in a separate step in order to form the high concentration layer 24 in the active layer 23. On the other hand, since the high concentration layer 24 can be formed in the active layer 23 by performing the heat treatment in this embodiment, the number of manufacturing steps can be reduced from that of the semiconductor device of the related art.

Note that the present invention is not limited to the exemplary embodiments described above, and various modifications may be made within the scope of the present invention without deviating from the gist thereof.

Further, it is noted that Applicant's intent is to encompass equivalents of all claim elements, even if amended later during prosecution.

What is claimed is:

1. A semiconductor device, comprising:
a substrate;
an insulating layer formed on the substrate;
an active layer formed on the insulating layer; and
a metal layer formed on a back surface of the substrate, the metal layer being in ohmic contact with the substrate.

2. The semiconductor device according to claim 1, wherein an impurity concentration of the substrate is 1×10¹⁸ cm⁻³ or higher.

3. The semiconductor device according to claim 2, wherein:
the active layer comprises:
an active region; and
a high concentration region whose impurity concentration is higher than that in the active region, and being formed on the active layer in contact with the insulating layer.

4. The semiconductor device according to claim 2, wherein:
the active layer has a trench which reaches the insulating film; and
an insulating layer is formed in the trench.

5. The semiconductor device according to claim 1, wherein:
the substrate includes:
a high concentration layer, whose an impurity concentration is 1×10¹⁸ cm⁻³ or higher, being in contact with the metal layer, and
a low concentration layer formed on the high concentration layer, the low concentration having an impurity concentration which is lower than that of the high concentration layer.

6. The semiconductor device according to claim 5, wherein
an impurity concentration of the low concentration layer is in a range of 1×10¹⁴ cm⁻³ to 1×10¹⁶ cm⁻³.

7. The semiconductor device according to claim 5, wherein the impurity concentration of the high concentration layer is 1×10¹⁹ cm⁻³ or higher.

8. A method of manufacturing a semiconductor device, comprising:
forming an insulating layer on a first surface of a substrate whose impurity concentration is 1×10¹⁸ cm⁻³ or higher;
forming an active layer on the insulating layer; and
forming a metal layer on a second surface of the substrate opposite to the first surface of the substrate so that the metal layer and the substrate are in ohmic contact.

9. The method according to claim 8, wherein
the substrate and the active layer are bonded with the insulating layer therebetween, and
impurities are diffused in the active layer by heat treatment.

10. The method according to claim 8, wherein the insulating layer and the active layer are formed by:
oxidizing the active layer to form the insulating layer on a surface of the active layer;
bonding the active layer, formed with the insulating layer, and the substrate; and
polishing the insulating layer until the active layer is exposed on a surface opposite to a surface to which the active layer is bonded.

11. The method according to claim 8, wherein the insulating layer and the substrate are formed by:
oxidizing the substrate to form the insulating layer on a surface of the substrate;
bonding the substrate, formed with the insulating layer, and the active layer, and removing an insulating film of the substrate; and
polishing the active layer from a surface opposite to a surface to which the active layer is bonded.

12. The method according to claim 8, wherein
the substrate is implanted with impurities to have a high concentration layer having the impurity concentration of 1×10¹⁸ cm⁻³ or higher while leaving a low concentration layer whose impurity concentration is lower than that of the high concentration layer; and
the metal layer is formed on the high concentration layer.

13. The method according to claim 12, wherein the insulating layer and the active layer are formed by:
oxidizing the active layer to form the insulating layer on a surface of the active layer;
bonding the active layer, formed with the insulating layer, and the low concentration substrate; and
polishing the insulating layer until the active layer is exposed on a surface of the insulating layer opposite to a surface to which the active layer is bonded.

14. The method according to claim 12, wherein the insulating layer and the substrate are formed by:
oxidizing the substrate to form the insulating layer on a surface of the substrate;
bonding the substrate, formed with the insulating layer, and the active layer; and
polishing the active layer from a surface opposite to a surface to which the active layer is bonded.

15. The method according to claim 12, wherein
an impurity concentration of the low concentration layer is in a range of 1×10¹⁴ cm⁻³ to 1×10¹⁶ cm⁻³.

16. The method according to claim 12, wherein the impurity concentration of the high concentration layer is 1×10¹⁹ cm⁻³ or higher.

17. A semiconductor device, comprising:
a semiconductor substrate whose impurity concentration is in a range of 1×10¹⁴ cm⁻³ to 1×10¹⁶ cm⁻³;
an insulating layer substantially entirely formed on a first surface of said semiconductor substrate;
an active layer formed on said insulating layer to constitute a silicon-on-insulator structure with said insulating layer;
an impurity layer substantially entirely formed on a second surface of said semiconductor substrate, said first surface being opposite to said second surface, said impurity layer having an impurity concentration being 1×10¹⁸ cm⁻³ or higher; and
a metal layer formed on said impurity layer.

18. The semiconductor device as claimed in claim 17, further comprising:
an insulator formed in said active layer to divide said active layer into a plurality of active layers.
